(19) United States
(12) Patent Application Publication
(10) Pub. No.: US 2012/0188160 A1
(43) Pub. Date: Jul. 26, 2012

(54) MOUSE WITH JOYSTICK

(75) Inventor: Brian William Wallace, Raleigh, NC (US)

(73) Assignee: LENOVO (Singapore) Pte. Ltd., Singapore (SG)

(21) Appl. No.: 13/014,564

(22) Filed: Jan. 26, 2011

(51) Int. Cl. G09G 5/08; B23P 11/00; H05K 13/00; G06F 3/033

(52) U.S. Cl. 345/161; 345/163; 345/167; 29/428; 29/825

(57) ABSTRACT

A device includes a mouse portion having multiple buttons and a base. The device further includes a joystick portion having a joystick extending to the base of the mouse portion and an upper surface movably mounted adjacent the base of the mouse portion such that relative movement between the base and upper surface results in movement of the joystick.

### BACKGROUND

Mouse input devices for computers are moved by user with their hands. The motion of the mouse is translated into cursor movements on a display device of the computer. Inevitably, arm motion is also utilized, leading to constant movement that may cause damage to the wrist and hands. Carpal tunnel syndrome is just one ailment that can result.

### SUMMARY

A device including a mouse portion having multiple buttons and a base. The device further includes a joystick portion having a joystick extending to the base of the mouse portion and an upper surface movably mounted adjacent the base of the mouse portion such that relative movement between the base and upper surface results in movement of the joystick.

A method includes placing a mouse housing having multiple buttons and a base on upper of a upper surface of a joystick portion. A joystick is attached to the base of the mouse portion though the upper surface of the joystick portion. The base of the mouse portion is movably mounted with the upper surface of the joystick portion such that relative movement between the base and upper surface results in movement of the joystick.

In a further embodiment, a device includes a mouse portion having multiple buttons including a right button, a left button, and a scroll wheel, and having circuitry coupled to the mouse buttons to provide signals representative of mouse button actuation, and having a base. A joystick portion has a joystick extending to the base of the mouse portion and an upper surface movably mounted adjacent the base of the mouse portion such that relative movement between the base and upper surface results in movement of the joystick. The joystick portion further includes circuitry coupled to the joystick to provide signals representative of movement of the joystick.

### BRIEF DESCRIPTION OF THE DRAWINGS

FIG. 1 is a cross section side view of a mouse with a joystick according to an example embodiment.

FIG. 2 is a top view of a mouse with a joystick according to an example embodiment.

FIG. 3 is a cross section view of the mouse of FIG. 1 illustrating joystick operation of the mouse according to an example embodiment.

FIG. 4 is a functional block diagram illustrating functions actuated by a combination mouse and joystick according to an example embodiment.

FIG. 5 is a side view of a further embodiment of a mouse having joystick operation according to an example embodiment.

FIG. 6 is a front view of the mouse of FIG. 5.

FIG. 7 is a block diagram of an information handling system utilizing a mouse with a joystick according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

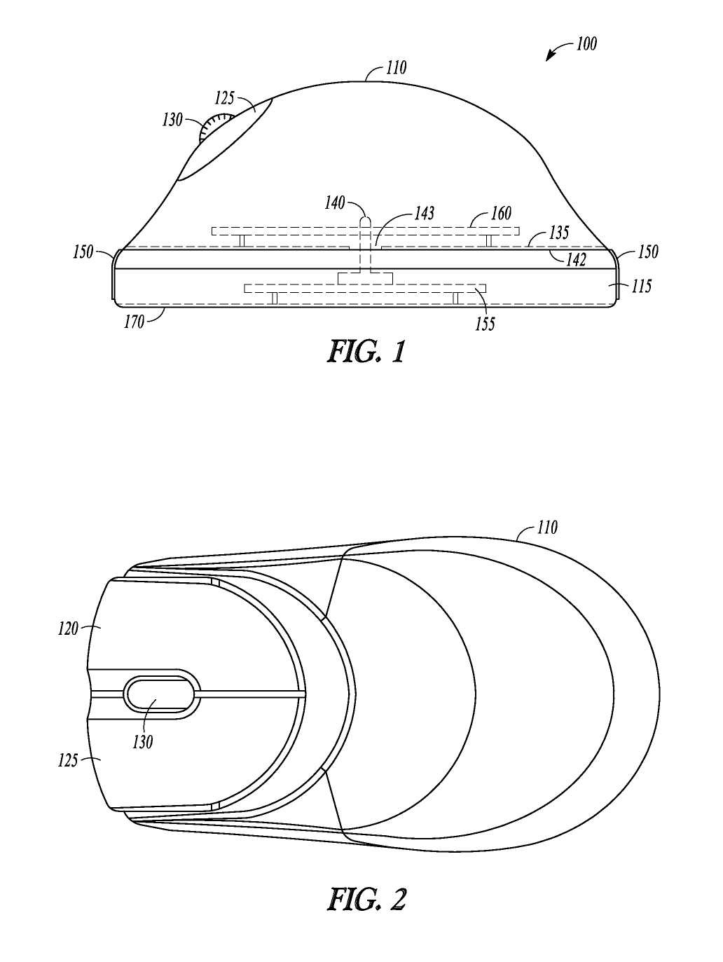

FIG. 1 is a cross section view of a mouse with a joystick according to an example embodiment indicated generally at 100. A mouse portion 110 is coupled to actuate a joystick portion 115. In one embodiment, the mouse is a standard three button mouse, with right 120 and left 125 buttons, and a scroll wheel 130 as seen in a front view of an alternative mouse in FIG. 2 utilizing the same reference numbers for like components. In further embodiments, the mouse may include just the right and left buttons.

The mouse portion 110 is movably or slideably mounted on the joystick portion 115, and has a base 135 to which a joystick 140 supported within the joystick portion 115 is coupled, or otherwise disposed within a hole in the base such that movement of the base 135 relative to the joystick portion 115 causes movement of the joystick 140. Movement of the joystick 140 may be translated into movement of a cursor or other construct on a display device when the mouse with joystick 100 is coupled to a computer system coupled to the display device. In further embodiments, different devices or functions may be controlled by movement of the joystick 140.

In some embodiments, the joystick 140 may be supported within the joystick portion 115 to provide a desired resistance to movement. The base 135 of the mouse portion 110 may interface with and be positioned adjacent to an upper surface 142 of the joystick portion 115. The resistance provided by the joystick 140 may provide suitable resistance to movement between the base 135 and an upper surface 142 of the joystick portion 115 to avoid unintentional movement and provide a tactile feel to a user moving a cursor. The upper surface 142 has an opening 143 in one embodiment to allow for movement of the joystick 140.

In some embodiments, the mouse portion 110 and joystick portion 115 may include a compliant band 150 coupled around a perimeter of the interface between the mouse portion 110 and joystick portion 115. The compliant band may be formed of rubber or a polymer or other material that provide a flexible shield to allow movement between the mouse portion 110 and joystick portion 115 while maintaining a desired tactile feel for the user and holding the combination of mouse portion 110 and joystick portion 115 together in an integrated manner. In further embodiments, keyed projections on the mouse portion 110 and joystick portion 115 may keep the base 135 and upper surface 142 together and permit a desired amount of sliding between them.

Joystick 140 in one embodiment is supported by a circuit board 155 that translates movements of the joystick 140 into signals to be sent to the computer, along with signals corresponding to mouse button actuation sent by a mouse portion circuit board 160. In further embodiments, the circuit boards may be supported within the respective mouse and joystick portions by posts, ridges, or other supports, and the portions may be formed of plastic or other suitable materials. In still further embodiments, the circuit boards may be replaced by other electronic components such as circuit chips or discrete components otherwise supported within the portions. In still further embodiments, the functions may be combined into a single electronic device located in the joystick portion, with a bus or wires coupled between the portions to provide signals from each portion.

In one embodiment, the joystick portion 115 has a bottom 170 formed with a non skid type of material such as rubber. The bottom 170 may also include filler material to add weight and help prevent the combination of mouse portion 110 and joystick portion 115 from sliding or otherwise moving during use.

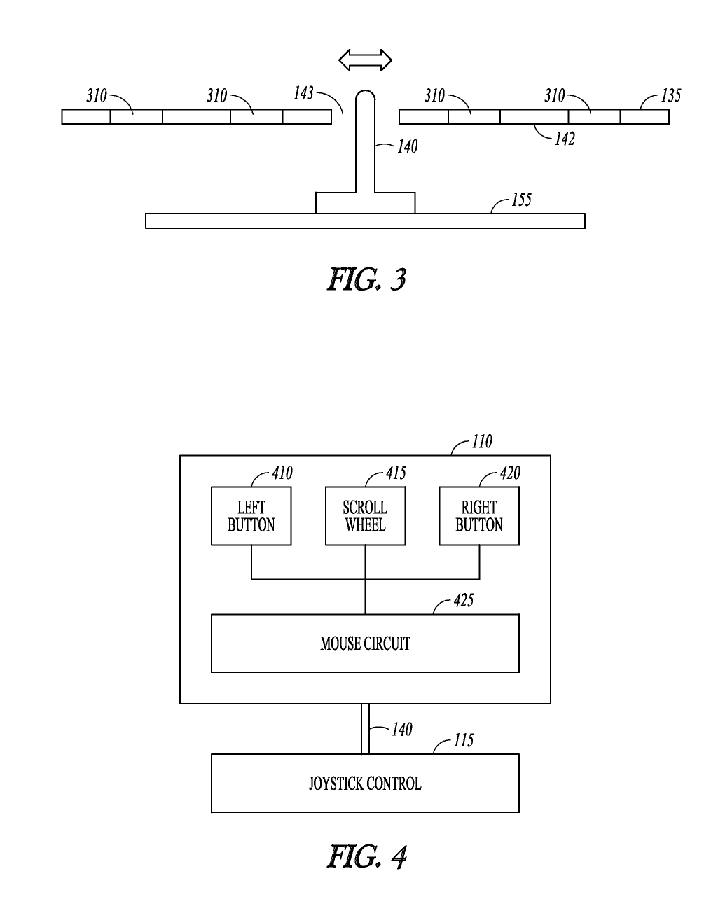

FIG. 3 is a cross section view of the mouse of FIG. 1 illustrating joystick operation of the mouse according to an example embodiment. Bottom portion 135 is separated from top portion 142 in one embodiment by one or more skid pads 310. The skid pads 310 may be attached to one or the other of the bottom portion 135 and top portion 142 and provide a sliding surface to facilitate movement between the top and bottom portions. The skid pads 310 may be formed of a polymer such as polytetrafluoroethylene (PTFE) in one embodiment. In further embodiments, the skid pads 310 may be replaced with a lubricant, or the top and bottom surfaces may be formed of two materials such as PTFE that allow desired movement of the surfaces relative to each other.

As can be seen more clearly in FIG. 3, stick 140 is coupled to the bottom surface 135 of mouse portion 110, and extends up from board 155 through hold or opening 143 in the top surface of joystick portion 115.

FIG. 4 is a functional block diagram illustrating functions actuated by a combination mouse and joystick according to an example embodiment. FIG. 4 illustrates the operation of the mouse portion 110 and joystick portion 115. In mouse portion 110, a left button is represented at 410, the scroll wheel is represented at 415, and the right button is represented at 420. Actuation of the buttons and scroll wheel is interpreted by a mouse circuit 425.

Joystick portion 115 includes a joystick control circuit 430 that is coupled to joystick 140. Movement of the joystick 140 is interpreted by joystick control circuit 430. Signals from the mouse circuit 425 are provided to a computer to provide signals to applications and other code running on the computer via a driver running on the computer. In one embodiment, the mouse selection buttons operate in the same manner as a standard mouse, and may be used to select functions and scroll. Similarly, signals from the joystick control circuit 115 are provided to the driver on the computer to control cursor motion in the same was as a normal joystick.

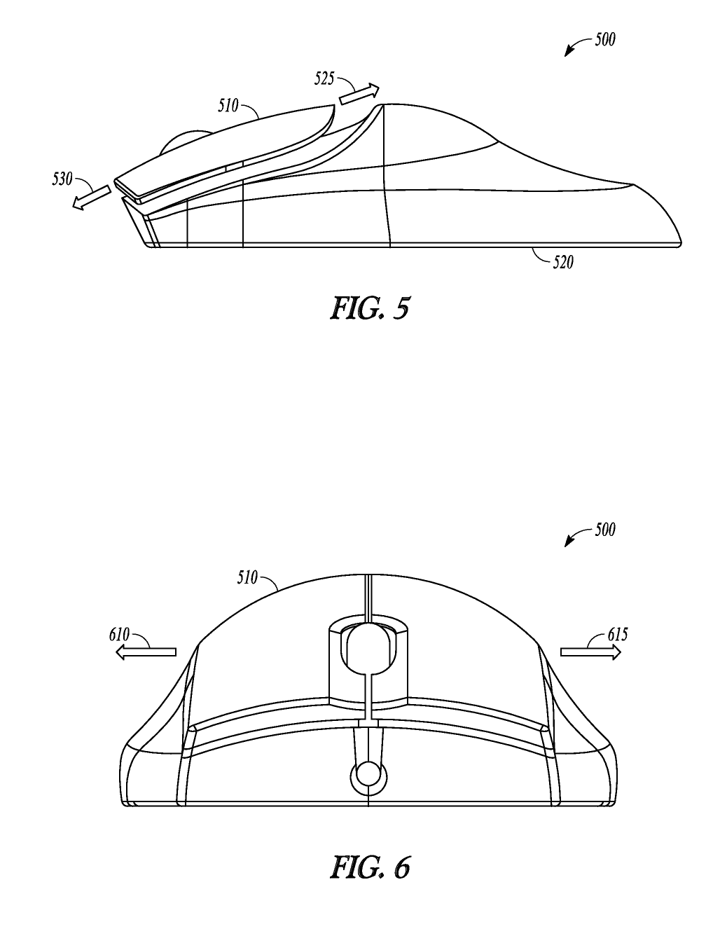

FIG. 5 is a side view of a further embodiment of a mouse 500 having joystick operation according to an example embodiment. Mouse 500 includes the two or more buttons in a button section 510 of the mouse 500 that is supported by a base 520. The button section in one embodiment moves separately from the base 520, and may be supported on a joystick 140 as seen in FIG. 1. In one embodiment, the button section 510 may correspond to the mouse portion 110 of FIG. 1 having a base coupled to the joystick 140. Arrows 525 and 530 illustrate one direction of movement of the button section 510. In some embodiments, the button section may move with same degree of freedom as a standard joystick, essentially in a plane transverse to the joystick 140. The joystick 140 may be tilted to be transverse to an angled plane formed by the position of the button section 510 relative to the base 520. In the embodiment shown, the button section 510 is tilted toward a front of the mouse 500. In further embodiments, the joystick 140 may be placed at different angles, including directly transverse to a bottom surface of the base 520.

In one embodiment, joystick 140 may be formed to move in response to very little force, allowing touching of the button section 510 to activate the joystick 140 without unintentionally activating a button.

FIG. 6 is a front elevation view of the mouse 500. The button section 510 is coupled to the joystick 140 as opposed to the entire top section of the mouse being coupled to the joystick as in FIG. 1. FIG. 6 also illustrates movement of the button section 510 and hence the joystick 140 as illustrated by arrows 610 and 615, providing movement transverse to arrows 525 and 530.

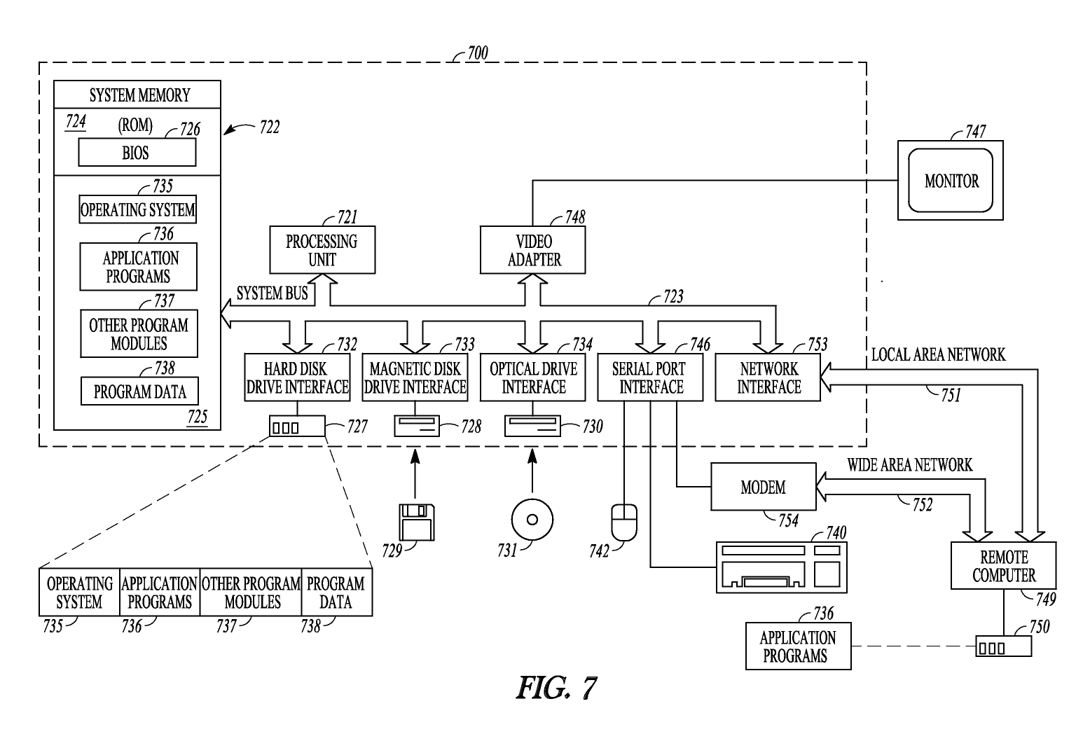

FIG. 7 is a block diagram of an information handling system utilizing a mouse with a joystick according to an example embodiment. In the embodiment shown in FIG. 7, a hardware and operating environment is provided that is applicable to any of the servers and/or remote clients shown in the other Figures.

As shown in FIG. 7, one embodiment of the hardware and operating environment includes a general purpose computing device in the form of a information handing device such as a computer 700 (e.g., a personal computer, workstation, server, slate, mobile phone, pad, server, and others), including one or more processing units 721, a system memory 722, and a system bus 723 that operatively couples various system components including the system memory 722 to the processing unit 721. There may be only one or there may be more than one processing unit 721, such that the processor of computer 700 comprises a single central-processing unit (CPU), or a plurality of processing units, commonly referred to as a multiprocessor or parallel-processor environment. In various embodiments, computer 700 is a conventional computer, a distributed computer, or any other type of computer.

The system bus 723 can be any of several types of bus structures including a memory bus or memory controller, a peripheral bus, and a local bus using any of a variety of bus architectures. The system memory can also be referred to as simply the memory, and, in some embodiments, includes read-only memory (ROM) 724 and random-access memory (RAM) 725. A basic input/output system (BIOS) program 726, containing the basic routines that help to transfer information between elements within the computer 700, such as during start-up, may be stored in ROM 724. The computer 700 further includes a hard disk drive 727 for reading from and writing to a hard disk, not shown, a magnetic disk drive 728 for reading from or writing to a removable magnetic disk 729, and an optical disk drive 730 for reading from or writing to a removable optical disk 731 such as a CD ROM or other optical media.

The hard disk drive 727, magnetic disk drive 728, and optical disk drive 730 couple with a hard disk drive interface 732, a magnetic disk drive interface 733, and an optical disk drive interface 734, respectively. The drives and their associated computer-readable media provide non volatile storage of computer-readable instructions, data structures, program modules and other data for the computer 700. It should be appreciated by those skilled in the art that any type of computer-readable media which can store data that is accessible by a computer, such as magnetic cassettes, flash memory cards, digital video disks, Bernoulli cartridges, random access memories (RAMs), read only memories (ROMs), redundant arrays of independent disks (e.g., RAID storage devices) and the like, can be used in the exemplary operating environment.

A plurality of program modules can be stored on the hard disk, magnetic disk 729, optical disk 731, ROM 724, or RAM 725, including an operating system 735, one or more application programs 736, other program modules 737, and program data 738. Programming for implementing one or more processes or method described herein may be resident on any one or number of these computer-readable media.

A user may enter commands and information into computer 700 through input devices such as a keyboard 740 and pointing device such as a 742. Mouse 742 in one embodiment is a mouse with a joystick as described above. Other input devices (not shown) can include a microphone, joystick, game pad, satellite dish, scanner, or the like. These other input devices are often connected to the processing unit 721 through a serial port interface 746 that is coupled to the system bus 723, but can be connected by other interfaces, such as a parallel port, game port, or a universal serial bus (USB). A monitor 747 or other type of display device can also be connected to the system bus 723 via an interface, such as a video adapter 748. The monitor 747 can display a graphical user interface for the user. In addition to the monitor 747, computers typically include other peripheral output devices (not shown), such as speakers and printers.

The computer 700 may operate in a networked environment using logical connections to one or more remote computers or servers, such as remote computer 749. These logical connections are achieved by a communication device coupled to or a part of the computer 700; other types of communication devices may also be used. The remote computer 749 can be another computer, a server, a router, a network PC, a client, a peer device or other common network node, and typically includes many or all of the elements described above 110 relative to the computer 700, although only a memory storage device 750 has been illustrated. The logical connections depicted in FIG. 7 include a local area network (LAN) 751 and/or a wide area network (WAN) 752. Such networking environments are commonplace in office networks, enterprise-wide computer networks, intranets and the internet, which are all types of networks.

When used in a LAN-networking environment, the computer 700 is connected to the LAN 751 through a network interface or adapter 753, which is one type of communications device. In some embodiments, when used in a WAN-networking environment, the computer 700 typically includes a modem 754 (another type of communications device) or any other type of communications device, e.g., a wireless transceiver, for establishing communications over the wide-area network 752, such as the internet. The modem 754, which may be internal or external, is connected to the system bus 723 via the serial port interface 746. In a networked environment, program modules depicted relative to the computer 700 can be stored in the remote memory storage device 750 of remote computer, or server 749. It is appreciated that the network connections shown are exemplary and other means of, and communications devices for, establishing a communications link between the computers may be used including hybrid fiber-coax connections, T1-T3 lines, DSL's, OC-3 and/or OC-12, TCP/IP, microwave, wireless application protocol, and any other electronic media through any suitable switches, routers, outlets and power lines, as the same are known and understood by one of ordinary skill in the art.

1. A device comprising:
a mouse portion having multiple buttons and a base; and
a joystick portion having a joystick extending to the base of the mouse portion and an upper surface movably mounted adjacent the base of the mouse portion such that relative movement between the base and upper surface results in movement of the joystick.

2. The device of claim 1 and further comprising circuitry coupled to the multiple buttons and the joystick to provide signals representative of selection of the buttons and movement of the joystick.

3. The device of claim 2 wherein the circuitry comprises a mouse circuit board and a joystick circuit board.

4. The device of claim 2 wherein the circuitry comprises a single circuit board that supports the joystick.

5. The device of claim 1 wherein the buttons comprises a right button, a left button, and a scroll wheel.

6. The device of claim 1 wherein the base and upper surface are separated from each other by skid pads.

7. The device of claim 1 and further comprising a band disposed about a perimeter of the base and upper surface.

8. The device of claim 1 wherein the upper surface has a hole about the joystick to allow movement of the joystick.

9. The device of claim 1 wherein the joystick is attached to the base.

10. A method comprising:
placing a mouse portion having multiple buttons on an upper surface of a joystick portion;
attaching a joystick to the mouse portion though the upper surface of the joystick portion; and
movably mounting the mouse portion with the upper surface of the joystick portion such that relative movement between the mouse portion and upper surface of the joystick portion results in movement of the joystick.

11. The method of claim 10 and further comprising coupling circuitry to the multiple buttons and the joystick to provide signals representative of selection of the buttons and movement of the joystick.

12. The method of claim 11 wherein the circuitry comprises a mouse circuit board and a joystick circuit board.

13. The method of claim 11 wherein the circuitry comprises a single circuit board that supports the joystick.

14. The method of claim 10 wherein the mouse portion and upper surface of the joystick portion are separated from each other by skid pads.

15. The method of claim 10 and further providing a band disposed about a perimeter of the mouse portion and upper surface of the joystick portion.

16. The method of claim 10 and further comprising providing a hole in the upper surface about the joystick to allow movement of the joystick.

17. The method of claim 10 wherein the joystick is attached to a base of the mouse portion.

18. A system comprising:
a processing unit;
a memory coupled to the processor to store code to execute on the processor;
a mouse portion having multiple buttons including a right button, a left button, and a scroll wheel, and having circuitry coupled to the mouse buttons to provide signals representative of mouse button actuation to the processor, and having a base; and
a joystick portion having a joystick extending to the base of the mouse portion and an upper surface movably mounted adjacent the base of the mouse portion such that relative movement between the base and upper surface results in movement of the joystick, and further including circuitry coupled to the joystick to provide signals representative of movement of the joystick.

19. The system of claim 18 and further comprising a system bus coupled between the processing unit, the mouse portion and the joystick portion, wherein the base and upper surface are separated from each other by skid pads, and further comprising a band disposed about a perimeter of the base and upper surface.

20. The system of claim 19 and further comprising a video adapter coupled to the system bus, wherein the upper surface has a hole about the joystick to allow movement of the joystick, and wherein the joystick is attached to the base.
